(19) United States
(12) Patent Application Publication
(10) Pub. No.: US 2003/0211411 A1
(43) Pub. Date: Nov. 13, 2003

(54) Method for monitoring focus in lithography

(76) Inventors: Chen-Cheng Yung, Hsinchu Hsien (TW); Chang-Hao Yang, Nan-Tou Hsien (TW)

Correspondence Address: BIRCH STEWART KOLASCH & BIRCH, PO BOX 747, FALLS CHURCH, VA, 22040-0747, US

(21) Appl. No.: 10/244,735

(22) Filed: Sep. 17, 2002

(30) Foreign Application Priority Data
May 8, 2002 (TW) 2002-91109593

(51) Int. Cl. G03F 7/207; G06K 9/00; G01N 21/00

(52) U.S. Cl. 430/30; 382/145; 356/237.5

(57) ABSTRACT

A method for monitoring focus in lithography. First, a mask having a plurality of substantially parallel line patterns is provided. Next, a wafer covered by a photoresist layer is exposed by the mask to form a plurality of exposure regions with different exposure focuses. Next, the photoresist layer on the wafer is developed to form a plurality of patterned regions having the line patterns. Thereafter, the wafer having the patterned regions is placed into an optical apparatus, and the line width variation in each of the patterned regions exposed by the different focuses is then checked. (Finally, the focus latitude is determined according to the line width variation in each of the patterned regions and the exposure focus thereof.

### BACKGROUND OF THE INVENTION

1. Field of the Invention

The present invention relates in general to a semiconductor process. In particular, the present invention relates a method for monitoring focus prior to lithography to determine focus.

2. Description of the Related Art

As the integration of integrated circuits (ICs) increases, lithography for pattern definition on a semiconductor wafer becomes more and more challenging. Lithography is used to transmit a pattern on a mask to a photoresist layer on a substrate through spatially modulated light. The photoresist layer is then developed and the exposed pattern is either removed or remains to form a three-dimensional image pattern in the photoresist layer. The image pattern can then be etched into the substrate or serve as a mask for implantation. However, if the quality of the image pattern that is developed in the photoresist layer is poor, many process steps for IC fabrication are wasted. Since the quality of the image pattern is affected by focus, image pattern generated through lithography requires monitoring to determine if the pattern is within an acceptable tolerance range (focus latitude).

FIG. 1 is a schematic diagram of a conventional stepper performing lithography for IC fabrication. Exposure light source 100 passes through an aperture 102 and a collimating lens 104 to form parallel light. Next, the parallel light passes through the transparent regions (not shown) of the mask 106 and reaches a projection lens 108. Finally, the image is transmitted to a photoresist layer (not shown) on a wafer 110 through the projection lens 108.

Current approaches for monitoring focus in lithography are laborious and time-consuming. For example, test patterns are formed near the scribe lines of the wafer, and critical dimension (CD) variations of the test patterns are then measured to determine if the focus is within an acceptable tolerance range.

### SUMMARY OF THE INVENTION

It is therefore an object of the present invention is to provide a method for monitoring focus in lithography to quickly and precisely determine the focus latitude by test patterns formed on the photoresist layer of the wafer using different exposure focuses.

According to an aspect of the invention, there is provided a method for monitoring focus in lithography. First, a mask having a plurality of substantially parallel line patterns is provided. Next, a substrate covered by a photoresist layer is exposed by the mask to form a plurality of exposure regions with different exposure focuses. Next, the photoresist layer on the substrate is developed to form a plurality of patterned regions having the line patterns. Thereafter, the substrate having the patterned regions is placed into an optical apparatus, and the line width variation in each of the patterned regions exposed by the different focuses is checked. Finally, focus latitude is determined according to the line width variation in each of the patterned regions and the exposure focuses thereof. Each of the line patterns has an equal width. Moreover, the exposure focuses are an arithmetic progression, and an arithmetical ratio of the arithmetic progression is 0.15.

### BRIEF DESCRIPTION OF THE DRAWINGS

The present invention can be more fully understood by reading the subsequent detailed description in conjunction with the examples and references made to the accompanying drawings, wherein:

FIG. 1 is a schematic diagram of a conventional stepper performing lithography.

FIG. 2a is a plane diagram showing one aspect of the test pattern on the mask according to the present invention.

FIG. 2b is a plane diagram showing another aspect of the test pattern on the mask according to the present invention.

FIG. 3 is a plane diagram showing test patterns formed on the wafer by different exposure focuses according to the present invention.

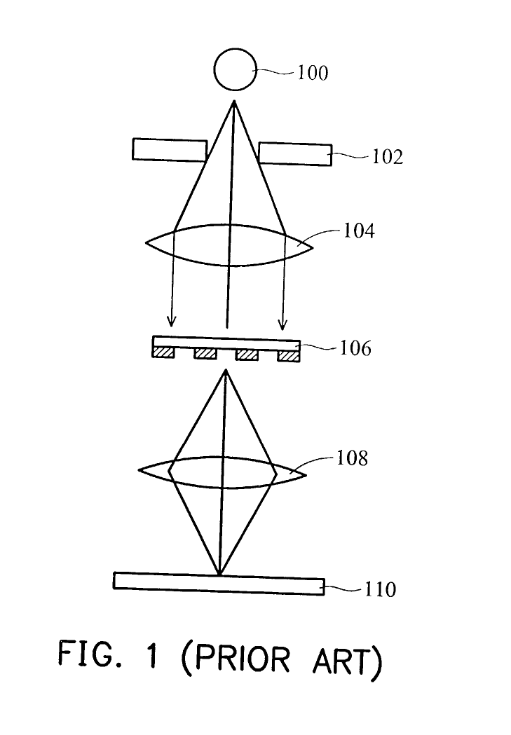

### DETAILED DESCRIPTION OF THE INVENTION

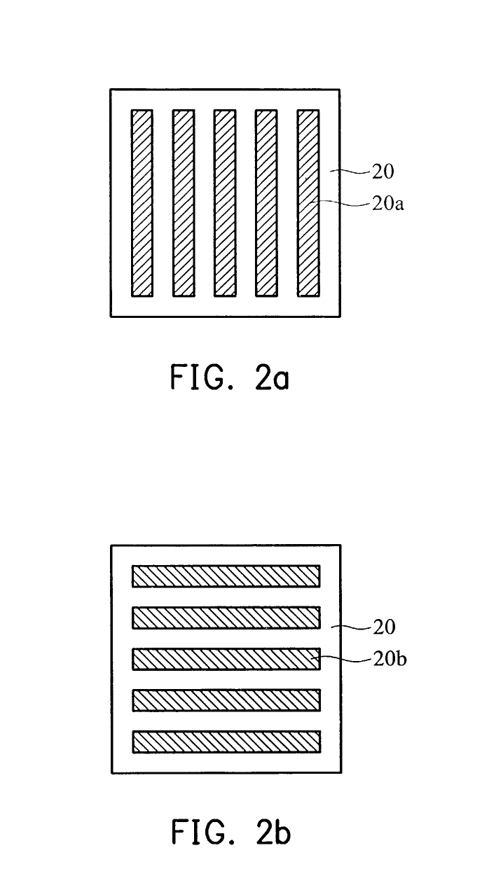

FIG. 2a is a plane diagram showing one aspect of the test pattern on the mask according to the present invention. In FIG. 2a, a test pattern 20a is formed on the mask 20 by conventional mask fabrication. In this invention, for example, the test pattern 20a is composed of a plurality of substantially parallel line patterns and these line patterns are longitudinally arranged. Moreover, each of the line patterns has an equal width and the spaces between the line patterns are equal.

FIG. 2b is a plane diagram showing another aspect of the test pattern on the mask according to the present invention. Also, in FIG. 2b, a test pattern 20b can be formed on the mask 20 by conventional mask fabrication. In this invention, for example, the test pattern 20b is composed of a plurality of substantially parallel line patterns transversely arranged. Moreover, each of the line patterns also has an equal width and the spaces between the line patterns are equal.

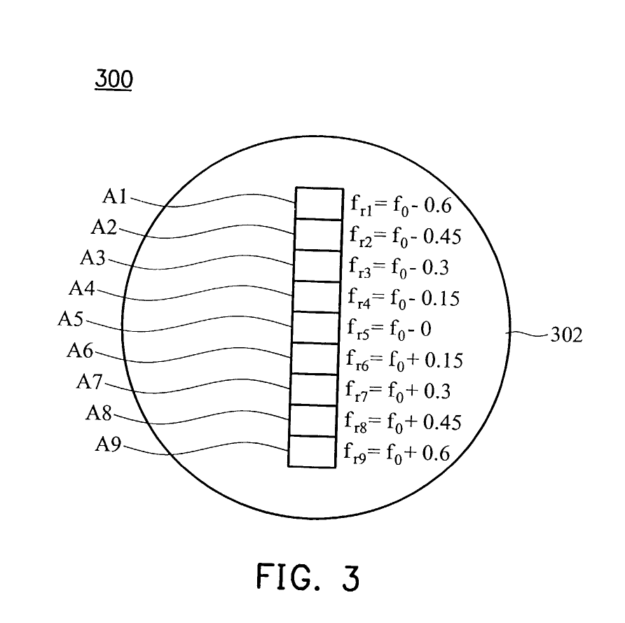

FIG. 3 is a plane diagram showing test patterns formed on the wafer by exposure at different focuses according to the present invention. In FIG. 3, in order to form a test pattern (as shown in FIG. 2a or 2b) on a wafer, first, the mask 20 having test pattern 20a or 20b is provided. Next, a substrate 300, such as a blank silicon wafer (hereinafter called control wafer), is provided. Thereafter, a photoresist layer 302 is coated on the control wafer 300.

Next, exposure is performed on the control wafer 300 covered by the photoresist layer 302 using the mask 20 shown in FIG. 2a or 2b. An initial focus f₀ (μm) is determined before exposure. Next, a relative focus fᵣ₁ is set to a lithography apparatus such as a stepper for performing exposure process. The relative focus fᵣ₁ is obtained by the initial focus f₀, subtracting a predetermined value. In the invention, for example, the predetermined value is 0.6 (μm), and the relative focus fᵣ₁ is f₀-0.6 (μm). Thereafter, an exposure region A1 is formed on the photoresist layer 302 through the lithography apparatus (not shown) using the relative focus fᵣ₁.

Next, the position of the control wafer 300 is changed from the stepper. For example, the control wafer 300 is shifted forward by the size of an exposure region. Thereafter, a new relative focus fᵣ₂ is set to the lithography apparatus to form a new exposure region A2 on the photoresist layer 302. For example, the relative focus fᵣ₂ is f₀-0.45 (μm).

Also, the other exposure regions A3 to A5 can be sequentially formed on the photoresist layer 302 according to the relative focuses fᵣ₃, fᵣ₄, and fᵣ₅. In the invention, for example, the relative focuses fᵣ₃, fᵣ₄, and fᵣ₅ are f₀-0.3 (μm), f₀-0.15 (μm), and f₀-0 (μm), respectively. Next, a relative focus fᵣ₆ is obtained by the initial focus f₀ added to a predetermined value. In the invention, for example, the predetermined value is 0.15 (μm), and the relative focus fᵣ₆ is f₀+0.15 (μm). Thereafter, the control wafer 300 can be shifted forward, and an exposure region A6 is then formed on the photoresist layer 302 through the lithography apparatus using the relative focus fᵣ₆. Thereafter, the exposure regions A7 to A9 are sequentially formed on the photoresist layer 302 according to the relative focuses fᵣ₇, fᵣ₈, and fᵣ₉. In the invention, for example, the relative focuses fᵣ₇, fᵣ₈, and fᵣ₉ are f₀+0.3 (μm), f₀+0.45 (μm), and f₀+0.6 (μm), respectively.

In the invention, these relative focuses fᵣ₁ to fᵣ₉ are an arithmetic progression, and the arithmetical ratio of the arithmetic progression is 0.15. In addition, there are nine exposure regions A1 to A9 formed over the control wafer 300. However, the present invention is not limited to the number of the exposure regions and the value of the arithmetical ratio. They can be determined by requirement.

Next, developing is performed on the photoresist layer 302 to transmit the test pattern 20a or 20b to the photoresist layer 302 through the mask 20. Thus, there are nine patterned regions (not shown) formed on the photoresist layer 302. Since these line patterns (test patterns) regions are formed by different exposure focuses, the line profile in each of the patterned regions may be deformed or change the line width due to an out of focus image.

Accordingly, a visual inspection is then performed on each of the patterned regions for determining focus latitude. First, the control wafer 300 having the patterned regions is placed into an optical apparatus such as an after developing inspection (ADI). Thereafter, the line width variation or deformation in each of the patterned regions exposed by the different exposure focuses fᵣ₁ to fᵣ₉ is visually checked. Finally, the focus latitude is determined according to the line width variation in each of the patterned regions and the exposure focus thereof. For example, if the minimum line width variation or the line deformation can be obtained from the patterned regions formed by focuses fᵣ₃ to fᵣ₇, the focus latitude is from fᵣ₃ to fᵣ₇. In addition, the exposure focus for lithography is one half of the sum of the fᵣ₃ and fᵣ₇ (i.e. (fᵣ₃+fᵣ₇)/2).

According to the present invention, focus latitude can be quickly and precisely determined to maintain the reliability of IC devices. In addition, the method for monitoring stepper or scanner focus according to the present invention can be performed before lithography to prevent reduction of the yield.

Finally, while the invention has been described by way of example and in terms of the preferred embodiment, it is to be understood that the invention is not limited to the disclosed embodiment. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for monitoring focus in lithography, comprising steps of:
providing a mask having a test pattern;
exposing a substrate covered by a photoresist layer by the mask to form a plurality of exposure regions with different exposure focuses;
developing the photoresist layer on the substrate to form a plurality of patterned regions having the test pattern; and
inspecting the patterned regions to determine a focus latitude.

2. The method as claimed in claim 1, wherein the test pattern is composed of a plurality of substantially parallel line patterns.

3. The method as claimed in claim 2, wherein each of the line patterns has an equal width.

4. The method as claimed in claim 2, wherein the step of inspecting the patterned regions further comprises the step of:
placing the substrate having the patterned regions into an optical apparatus;
checking the line width variation in each of the patterned regions exposed by the different focuses; and
determining the focus latitude according to the line width variation in each of the patterned regions and the exposure focus thereof.

5. The method as claimed in claim 4, wherein the optical apparatus is an after developing inspection.

6. The method as claimed in claim 1, wherein the substrate is a blank silicon wafer.

7. The method as claimed in claim 1, wherein the exposure focuses are an arithmetic progression.

8. The method as claimed in claim 7, wherein an arithmetical ratio of the arithmetic progression is 0.15.

9. A method for monitoring focus in lithography, comprising steps of:
providing a mask having a plurality of substantially parallel line patterns;
exposing a wafer covered by a photoresist layer by the mask to form a plurality of exposure regions with different exposure focuses, wherein the exposure focuses are an arithmetic progression;
developing the photoresist layer on the wafer to form a plurality of patterned regions having the line patterns;
placing the wafer having the patterned regions into an optical apparatus;
checking the line width variation or deformation in each of the patterned regions exposed by the different focuses; and
determining the focus latitude according to the line width variation or deformation in each of the patterned regions and the exposure focus thereof.

10. The method as claimed in claim 9, wherein the line patterns are transversely or longitudinally arranged.

11. The method as claimed in claim 9, wherein the wafer is a control wafer for testing.

12. The method as claimed in claim 9, wherein each of the line patterns has an equal width.

13. The method as claimed in claim 9, wherein the optical apparatus is an after developing inspection.

14. The method as claimed in claim 9, wherein an arithmetical ratio of the arithmetic progression is 0.15.
